(19) United States
(12) Patent Application Publication
(10) Pub. No.: US 2017/0287796 A1
(43) Pub. Date: Oct. 5, 2017

(54) ELECTRONIC COMPONENT PACKAGE

(71) Applicant: SAMSUNG ELECTRO-MECHANICS CO., LTD., Suwon-si (KR)

(72) Inventors: Yun Tae LEE, Suwon-si (KR); Moon Il KIM, Suwon-si (KR)

(21) Appl. No.: 15/442,927

(22) Filed: Feb. 27, 2017

(30) Foreign Application Priority Data
Mar. 31, 2016 (KR) 10-2016-0039254

(51) Int. Cl. H01L 23/055; H01L 23/48; H05K 5/06; H05K 5/00; H05K 5/02; H05K 7/02; H01L 23/31

(52) U.S. Cl. CPC H01L 23/055; H05K 7/023; H01L 23/481; H01L 23/3157; H05K 5/0021; H05K 5/0217; H05K 5/0247; H05K 5/065

(57) ABSTRACT

An electronic component package includes: a lower package, including a frame including a through-hole and a through-wiring, a first electronic component disposed in the through-hole of the frame, a redistribution layer disposed below the first electronic component and the frame and electrically connected to the first electronic component, and an encapsulant filling the through-hole to encapsulate the first electronic component; an upper package disposed on the lower package and including a second electronic component; and a passive element disposed between the upper package and the lower package.

### CROSS-REFERENCE TO RELATED APPLICATION(S)

This application claims benefit of priority to Korean Patent Application No. 10-2016-0039254, filed on Mar. 31, 2016 in the Korean Intellectual Property Office, the disclosure of which is incorporated herein by reference in its entirety.

### TECHNICAL FIELD

The present disclosure relates to an electronic component package.

### BACKGROUND

An electronic component package is defined as a package technology for electrically connecting an electronic component to a printed circuit board (PCB), such as a main board of an electronic device, or the like, and protecting the electronic component from external impacts. Meanwhile, one recent main trend in the development of technology related to electronic components is to reduce the size of the electronic components. As such, in the package field, and in accordance with a rapid increase in demand for miniaturized electronic components, or the like, implementation of an electronic component package having a compact size and including a plurality of pins has been demanded.

One package technology suggested in order to satisfy the technical demand described above is a wafer level package (WLP) using the redistribution of an electrode pad of an electronic component formed on a wafer. An example of the wafer level package includes a fan-in wafer level package and a fan-out wafer level package. In particular, the fan-out wafer level package has a compact size and is advantageous in implementing a plurality of pins. Therefore, recently, the fan-out wafer level package has been actively developed.

In recent electronic component packages, in accordance with the desire to improve performance and miniaturize electronic devices, an attempt to dispose as many electronic components, passive elements, or the like, as possible in a limited space of the electronic component package has been continuously made.

### SUMMARY

An aspect of the present disclosure may provide an electronic component package in which a plurality of elements may be mounted in a small space.

One of several solutions suggested through the present disclosure may be to secure mounting efficiency and implement miniaturization of a package by disposing a passive element between an upper package and a lower package. According to an aspect of the present disclosure, an electronic component package may include: a lower package, including a frame including a through-hole and a through-wiring, a first electronic component disposed in the through-hole of the frame, a redistribution layer disposed below the first electronic component and the frame and electrically connected to the first electronic component, and an encapsulant filling the through-hole to encapsulate the first electronic component; an upper package disposed on the lower package and including a second electronic component; and a passive element disposed between the upper package and the lower package.

The electronic component package may further include a conductive adhesive layer connecting the upper package and the lower package to each other.

The conductive adhesive layer may be a solder.

A height of the conductive adhesive layer may be higher than that of the passive element.

The passive element may be disposed to be spaced apart from the upper package.

A plurality of conductive adhesive layers may be provided, and may be disposed to surround the passive element.

The passive element may be mounted on the lower package, and may be electrically connected to the lower package.

The electronic component package may further include an additional passive element disposed below the lower package.

The through-wiring may electrically connect the upper package and the lower package to each other.

The encapsulant may cover an upper portion of the frame. The lower package may further include a conductive via penetrating therethrough a portion of the encapsulant covering the upper portion of the frame and electrically connected to the through-wiring.

The first electronic component may be an active element, and the second electronic component may be a memory element.

The passive element may be connected to the first electronic component by power patterns of wiring layers included in the lower package.

The passive element may be a decoupling capacitor.

### BRIEF DESCRIPTION OF DRAWINGS

The above and other aspects, features, and advantages of the present disclosure will be more clearly understood from the following detailed description taken in conjunction with the accompanying drawings, in which:

FIG. 1 is a schematic block diagram illustrating an example of an electronic device system;

FIG. 2 is a schematic view illustrating an example of an electronic component package used in an electronic device;

FIG. 3 is a schematic cross-sectional view illustrating an example of an electronic component package; and

FIG. 4 is a schematic cross-sectional view illustrating a modified example of the electronic component package of FIG. 3.

### DETAILED DESCRIPTION

Hereinafter, exemplary embodiments in the present disclosure will be described with reference to the accompanying drawings. In the accompanying drawings, shapes, sizes, and the like, of components may be exaggerated or shortened for clarity.

Electronic Device

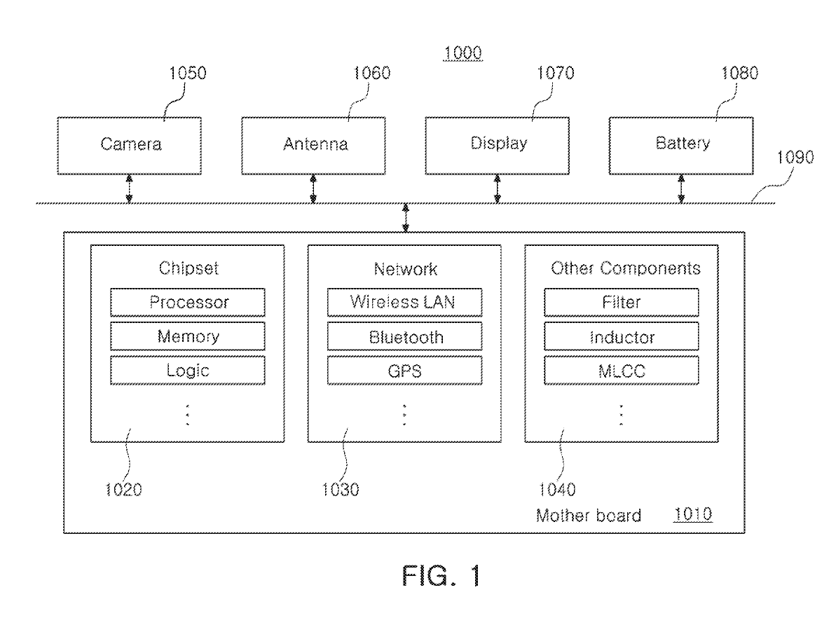

FIG. 1 is a schematic block diagram illustrating an example of an electronic device system.

Referring to FIG. 1, an electronic device 1000 may accommodate a motherboard 1010 therein. The motherboard 1010 may include chip related components 1020, network related components 1030, other components 1040, and the like, physically or electrically connected thereto. These components may be connected to other components, to be described below, to form various signal lines 1090.

The chip related components 1020 may include a memory chip such as a volatile memory (for example, a dynamic random access memory (DRAM)), a non-volatile memory (for example, a read only memory (ROM)), a flash memory, etc.; an application processor chip such as a central processor (for example, a central processing unit (CPU)), a graphics processor (for example, a graphic processing unit (GPU)), a digital signal processor, a cryptographic processor, a microprocessor, a microcontroller, etc.; a logic chip such as an analog-to-digital converter, an application-specific integrated circuit (ASIC), etc.; and the like. However, the chip related components 1020 are not limited thereto, but may also include other types of chip related components. In addition, the chip related components 1020 may be combined with each other.

The network related components 1030 may include protocols such as wireless fidelity (Wi-Fi) (Institute of Electrical and Electronics Engineers (IEEE) 802.11 family, or the like), worldwide interoperability for microwave access (WiMAX) (IEEE 802.16 family, or the like), IEEE 802.20, long term evolution (LTE), evolution data only (Ev-DO), high speed packet access+(HSPA+), high speed downlink packet access+(HSDPA+), high speed uplink packet access+(HSUPA+), enhanced data GSM environment (EDGE), global system for mobile communications (GSM), global positioning system (GPS), general packet radio service (GPRS), code division multiple access (CDMA), time division multiple access (TDMA), digital enhanced cordless telecommunications (DECT), Bluetooth, 3G, 4G, 5G protocols and any other wireless and wired protocols designated since the designation of the above-mentioned protocols. However, the network related components 1030 are not limited thereto, but may also include any of a plurality of other wireless or wired standards or protocols. In addition, these components 1030 may be combined with each other, together with the chip related components 1020 described above.

Other components 1040 may include a high frequency inductor, a ferrite inductor, a power inductor, ferrite beads, a low temperature co-fired ceramic (LTCC), an electromagnetic interference (EMI) filter, a multilayer ceramic capacitor (MLCC), or the like. However, other components 1040 are not limited thereto, but may also include passive components used for various other purposes, or the like. In addition, other components 1040 may be combined with each other, together with the chip related components 1020 or the network related components 1030 described above.

Depending on a kind of the electronic device 1000, the electronic device 1000 may include other components that may or may not be physically or electrically connected to the motherboard 1010. These other components may include, for example, a camera module 1050, an antenna 1060, a display 1070, a battery 1080, an audio codec (not illustrated), a video codec (not illustrated), a power amplifier (not illustrated), a compass (not illustrated), an accelerometer (not illustrated), a gyroscope (not illustrated), a speaker (not illustrated), a mass storage (for example, a hard disk drive) (not illustrated), a compact disk (CD) (not illustrated), a digital versatile disk (DVD) (not illustrated), and the like. However, these other components are not limited thereto, but may also include other components used for various purposes depending on a kind of electronic device 1000.

The electronic device 1000 may be a smartphone, a personal digital assistant (PDA), a digital video camera, a digital still camera, a network system, a computer, a monitor, a tablet personal computer (PC), a laptop PC, a netbook PC, a television, a video game machine, a smartwatch, or the like. However, the electronic device 1000 is not limited thereto, and may be any other electronic device processing data.

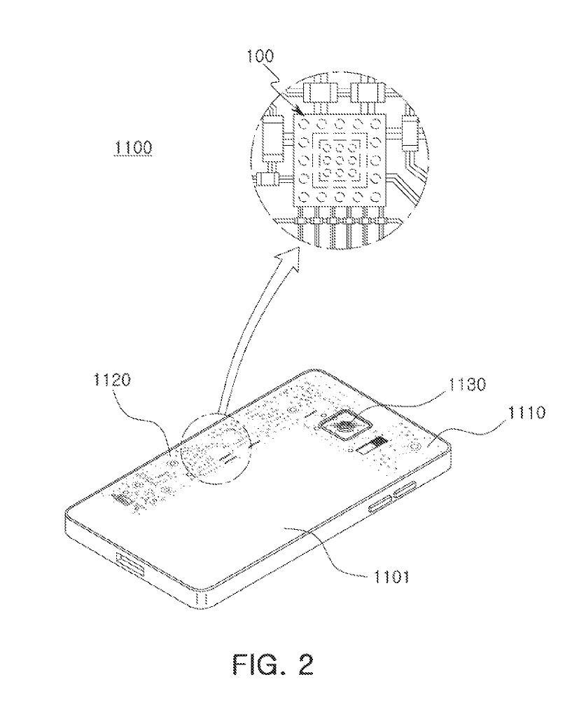

FIG. 2 is a schematic view illustrating an example of an electronic component package used in an electronic device.

The electronic component package may be used for various purposes in the various electronic devices 1000 as described above. For example, a main board 1110 may be accommodated in a body 1101 of a smartphone 1100, and various electronic components 1120 may be physically or electrically connected to the main board 1110. In addition, other components that may or may not be physically or electrically connected to the main board 1110, such as a camera module 1130, may be accommodated in the body 1101. In this case, some of the electronic components 1120 may be the chip related components described above, and the electronic component package 100 may be, for example, an application processor among the chip related components, but is not limited thereto.

Electronic Component Package

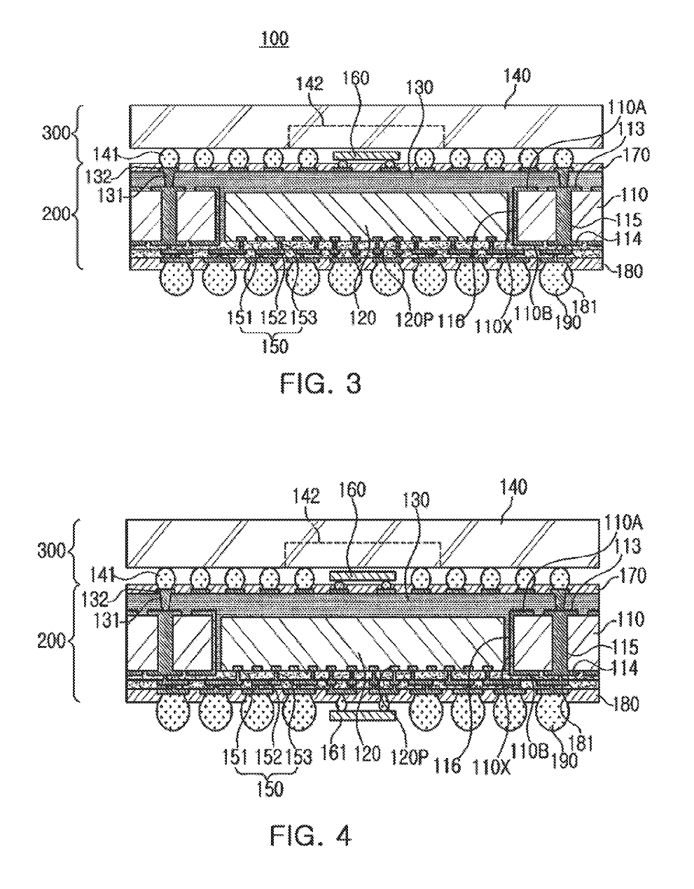

FIG. 3 is a schematic cross-sectional view illustrating an example of an electronic component package, while FIG. 4 is a schematic cross-sectional view illustrating a modified example of the electronic component package of FIG. 3.

Referring to FIG. 3, an electronic component package 100 according to an example may have a package-on-package structure, including a lower package 200 and an upper package 300, and may include a passive element 160 disposed between the lower package 200 and the upper package 300.

The lower package 200 may include a frame 110, a first electronic component 120, and a redistribution layer 150, as main components thereof. The main components and additional components of the lower package 200 will hereinafter be described in more detail.

The frame 110, which is provided to support the lower package 200, may maintain rigidity of the lower package 200 and secure uniformity of a thickness of the lower package 200, and may include a through-hole (a region in which the first electronic component 120 is disposed, in FIG. 3) and a plurality of through-wirings 115. The frame 110 may have an upper surface 110A and a lower surface 110B, opposing the upper surface 110A. In this case, the through-hole may penetrate between the upper surface 110A and the lower surface 110B. The first electronic component 120 may be disposed in the through-hole so as to be spaced apart from the frame 110 by a predetermined distance. As a result, side surfaces of the first electronic component 120 may be surrounded by the frame 110.

A material of the frame 110 is not particularly limited, as long as the frame may support the electronic component package. For example, an insulating material may be used as a material of the frame 110. In this case, the insulating material may be a thermosetting resin such as an epoxy resin, a thermoplastic resin such as a polyimide resin, a resin having a reinforcement material such as a glass fiber or an inorganic filler impregnated in the thermosetting resin and the thermoplastic resin, such as pre-preg, Ajinomoto Buildup Film (ABF), FR-4, Bismaleimide Triazine (BT), copper clad laminate (CCL), or the like. Alternatively, a metal having excellent rigidity and thermal conductivity may be used as a material of the frame 110. In this case, the metal may be an Fe—Ni based alloy. In this case, a copper plating may also be formed on a surface of the Fe—Ni based alloy in order to secure adhesion between the Fe—Ni based alloy and a molding material, an interlayer insulating material, or the like. In addition to the materials described above, glass, ceramic, plastic, or the like, may also be used as a material of the frame.

A thickness of the frame 110 in a cross section thereof is not particularly limited, but may be designed, depending on a thickness of the first electronic component 120 in a cross section thereof. For example, a thickness of the frame 110 in the cross section thereof may be about 100 μm to 500 μm, depending on a kind of first electronic component 120. The frame 110 may include one layer or a plurality of layers. In a case in which the frame 110 includes the plurality of layers, wiring layers may be disposed between the plurality of layers. In this case, the thicknesses of respective layers are not particularly limited, and an entire thickness of the total number of respective layers may be adjusted, as described above.

As in a form illustrated in FIG. 3, the frame 110 may include a first wiring layer 113 formed on the upper surface 110A thereof, a second wiring layer 116 formed on an inner wall 110X thereof, a third wiring layer 114 formed on the lower surface 110B thereof, and through-wirings 115 penetrating therethrough.

The first wiring layer 113 may serve as a redistribution pattern, and a conductive material such as copper (Cu), aluminum (Al), silver (Ag), tin (Sn), gold (Au), nickel (Ni), lead (Pd), titanium (Ti), or alloys thereof, may be used as a material of the first wiring layer 113. The first wiring layer 113 may perform various functions, depending on a design of the corresponding layer. For example, the first wiring layer 113 may serve as a ground pattern, a power pattern, a signal pattern, and the like. Here, the signal pattern may include various signals, such as data signals, and the like, except for the ground pattern, the power pattern, and the like. In addition, the first wiring layer 113 may serve as a via pad, a connection terminal pad, and the like. A thickness of the first wiring layer 113 is not particularly limited, but may be, for example, about 10 μm to 50 μm.

The second wiring layer 116 may basically disperse heat generated from the first electronic component 120 so as to be diffused toward the frame 110, and may block an electromagnetic wave. The second wiring layer 116 may also perform various functions depending on a design thereof, and may serve as a ground pattern. The second wiring layer 116 may be disposed on the inner wall 110X of the frame 110. Therefore, the second wiring layer 116 may surround the side surfaces of the first electronic component 120. The second wiring layer 116 may be formed to completely cover the inner wall 110X of the frame 110. Copper (Cu), aluminum (Al), silver (Ag), tin (Sn), gold (Au), nickel (Ni), lead (Pd), titanium (Ti), or alloys thereof, may be used as a material of the second wiring layer 116.

The third wiring layer 114 may serve as a redistribution pattern, and a conductive material such as copper (Cu), aluminum (Al), silver (Ag), tin (Sn), gold (Au), nickel (Ni), lead (Pd), titanium (Ti), or alloys thereof, may be used as a material of the third wiring layer 114. The third wiring layer 114 may also perform various functions depending on a design of the corresponding layer. For example, the third wiring layer 114 may serve as a ground pattern, a power pattern, a signal pattern, and the like. Similar to the first wiring layer 113, the signal pattern may include various signals, such as data signals, and the like, except for the ground pattern, the power pattern, and the like. In addition, the third wiring layer 114 may serve as a via pad, a connection terminal pad, and the like. A thickness of the third wiring layer 114 is also not particularly limited, but may be, for example, about 10 μm to 50 μm.

The through-wirings 115 may penetrate through the frame 110, and serve to electrically connect redistribution layers disposed on different layers, in relation to the frame 110, to each other. The lower package 200 and the upper package 300 may be electrically connected to each other by the through-wirings 115. A conductive material such as copper (Cu), aluminum (Al), silver (Ag), tin (Sn), gold (Au), nickel (Ni), lead (Pd), titanium (Ti), or alloys thereof, may be used as materials of the through-wirings 115. Upper and lower sides of the first electronic component 120 may be electrically connected to each other through left and right side surfaces of the first electronic component 120 via the through-wirings 115. Therefore, space utilization may be significantly increased. In addition, the electronic component package may be applied to a package-on-package (PoP), a system-in-package (SiP), or the like, by being connected in a three-dimensional structure, so that the electronic component package may be applied to various modules, package applied product groups, or the like.

The number, an interval, a disposition form, and the like, of through-wirings 115 are not particularly limited, but may be sufficiently modified depending on design particulars by those skilled in the art. The through-wirings 115 may be connected to pad patterns of the first and third wiring layers 113 and 114. For example, the through-wirings 115 may be disposed in an entire region of the frame 110, depending on a form of another package mounted on the electronic component package 100. Alternatively, the through-wirings 115 may be disposed in only a specific region of the frame 110.

In a case in which a metal such as an Fe—Ni based alloy, or the like, is used as a material of the frame 110, an insulating material may be disposed between the metal and the through-wirings 115 in order to electrically insulate the metal and the through-wirings 115 from each other. A shape of a cross section of the through-wiring 115 is not particularly limited, but may be a known shape such as a tapered shape, a sandglass shape, a pillar shape, or the like. The through-wiring 115 may be completely filled with a conductive material, as illustrated in FIG. 3, but is not limited thereto. That is, a conductive material may be formed along a wall of a via.

The first electronic component 120 may be an integrated circuit (IC) provided in an amount of several hundreds to several millions of elements or more, integrated in a single chip, an active element, or the like. The first electronic component 120 may be an electronic component in which an integrated circuit is packaged in a flip-chip form, if necessary. The IC may be, for example, an application processor chip such as a central processor (for example, a CPU), a graphic processor (for example, a GPU), a digital signal processor, a cryptographic processor, a microprocessor, a microcontroller, or the like, but is not limited thereto.

The first electrode component 120 may include electrode pads 120P formed for the purpose of electrical connection. The electronic pad 120P may be configured to electrically, externally connect to the first electronic component 120, and a material of the electrode pad 120P is not particularly limited as long as it is a conductive material. The conductive material may be copper (Cu), aluminum (Al), silver (Ag), tin (Sn), gold (Au), nickel (Ni), lead (Pd), titanium (Ti), or alloys thereof, but is not limited thereto. The electrode pad 120P may have an embedded form or a protruding form. A surface on which the electrode pads 120P are formed may become an active surface, and an opposite surface to the active surface may become an inactive surface.

In a case in which the first electronic component 120 is an integrated circuit, the first electronic component 120 may have a body (not denoted by a reference number), a passivation layer (not denoted by a reference number), and the electrode pads 120P. The body may be formed on the basis of, for example, an active wafer. In this case, silicon (Si), germanium (Ge), gallium arsenide (GaAs), or the like, may be used as a basic material of the body. The passivation layer may serve to protect the body from external factors, and may be formed of, for example, an oxide layer, a nitride layer, or the like, or may be formed of a double layer of an oxide layer and a nitride layer. The electrode pad 120P may include a conductive material, such as copper (Cu), aluminum (Al), silver (Ag), tin (Sn), gold (Au), nickel (Ni), lead (Pd), titanium (Ti), or alloys thereof, as described above.

A thickness of the first electronic component 120 in a cross section thereof is not particularly limited, but may be changed depending on a kind of first electronic component 120. For example, in the case in which the first electronic component is the integrated circuit, a thickness of the first electronic component may be about 100 μm to 480 μm, but is not limited thereto.

An encapsulant 130 may be used in order to protect the first electronic component 120, and the like, as in the form illustrated in FIG. 3. A form of the encapsulant 130 is not particularly limited, but may be a form surrounding at least portions of the first electronic component 120. As in the form illustrated in FIG. 3, as an example, the encapsulant 130 may cover the frame 110 and the first electronic component 120, and fill a space between the frame 110 and the first electronic component 120 within the through-hole. Therefore, the encapsulant 130 may serve as an adhesive, and may reduce buckling of the first electronic component 120, depending on certain materials. In this case, conductive vias 131 penetrating through the encapsulant 130 may be provided in order to electrically connect the lower package 200 and the upper package 300 to each other. The conductive vias 131 may connect wiring layers 113 and 132 to each other. However, unlike the form illustrated in FIG. 3, the encapsulant 130 may also be provided in a form in which it does not cover at least one of the first electronic component 120 and the frame 110.

The certain materials of the encapsulant 130 are not particularly limited. For example, an insulating material may be used as a material of the encapsulant 130. In this case, the insulating material may be a thermosetting resin such as an epoxy resin, a thermoplastic resin such as a polyimide resin, a resin having a reinforcement material such as an organic or inorganic filler impregnated in the thermosetting resin and the thermoplastic resin, or the like. Alternatively, the insulating material may be an epoxy molding compound (EMC), or the like.

The redistribution layer 150 may be disposed below the first electronic component 120, and may be electrically connected to the first electronic component 120 and be configured to redistribute electrode pads 120P of the electronic component 120. Tens to hundreds of electrode pads 120P, having various functions, may be redistributed through the redistribution layer 150 and may be physically or electrically, externally connected through connection terminals 190, depending on the functions thereof. The redistribution layer 150 may include insulating layers 151, wiring layers 152 formed on the insulating layers 151, and conductive vias 153 penetrating through the insulating layers 151. The redistribution layer 150 may be a single layer or a plurality of layers.

Insulating materials may be used as materials of the insulating layers 151. Particularly, in a case in which photosensitive resins are used as materials of the insulating layers, the insulating layers 151 may be formed at a reduced thickness, and a fine pitch may be easily implemented. Materials of the insulating layers 151 may be the same as each other or may be different from each other, if necessary. Thicknesses of the insulating layers 151 are also not particularly limited. For example, thicknesses of the insulating layers 151, except for the wiring layers 152, may be about 5 μm to 20 μm, and thicknesses of the insulating layers 151, when including thicknesses of the wiring layers 152, may be about 15 μm to 70 μm.

The wiring layers 152 may serve as redistribution patterns, and a conductive material such as copper (Cu), aluminum (Al), silver (Ag), tin (Sn), gold (Au), nickel (Ni), lead (Pd), titanium (Ti), or alloys thereof, may be used as materials of the wiring layers 152.

A surface treatment layer may be further formed on a wiring layer externally exposed among the wiring layers 152, if necessary. The surface treatment layer is not particularly limited as long as it is known in the related art, and may be formed by, for example, electrolytic gold plating, electroless gold plating, organic solderability preservative (OSP) or electroless tin plating, electroless silver plating, electroless nickel plating/substituted gold plating, direct immersion gold (DIG) plating, hot air solder leveling (HASL), or the like. This may also be applied to other wiring layers, and the like.

The conductive vias 153 may electrically connect the wiring layers 152, the electrode pads 120P, and the like, formed on different layers from each other, resulting in an electrical path in the electronic component package 100. Conductive materials such as copper (Cu), aluminum (Al), silver (Ag), tin (Sn), gold (Au), nickel (Ni), lead (Pd), titanium (Ti), or alloys thereof, may be used as materials of the conductive vias 153. The conductive vias 153 may also be completely filled with a conductive material. Alternatively, a conductive material may be formed along walls of the conductive vias 153. In addition, the conductive vias 153 may be in any of the cross sectional shapes known in the related art, such as a tapered shape, a cylindrical shape, or the like.

Passivation layers 170 and 180 may be formed on upper and lower portions of the lower package 200, respectively, and may be configured to protect the wiring layer 132, the redistribution layer 150, or the like, from external physical or chemical damage, or the like. The passivation layers 170 and 180 may expose at least portions of the wiring layers 132 and 152. For example, the passivation layer 180 may include openings 181. Although the openings 181 expose portions of one surface of the wiring layer 152, the openings 181 may also expose side surfaces of the wiring layer 152, in some cases.

Materials of the passivation layers 170 and 180 are not particularly limited. For example, a solder resist may be used as a material of the passivation layers 170 and 180. In addition, the same material as that of the insulating layer 151 of the redistribution layer 150, such as the photosensitive resin, may also be used as a material of the passivation layers 170 and 180. The passivation layer 180 is generally a single layer, but may also consist of multiple layers.

The connection terminals 190 may be configured to physically and electrically, externally connect the electronic component package 100. For example, the electronic component package 100 may be mounted on the main board of the electronic device through the connection terminals 190. The connection terminals 190 may be disposed on the openings 181, and may be connected to the wiring layer 152 exposed through the openings 181. Therefore, the connection terminals 190 may also be electrically connected to the first electronic component 120.

The connection terminal 190 may be formed of a conductive material, such as copper (Cu), aluminum (Al), silver (Ag), tin (Sn), gold (Au), nickel (Ni), lead (Pd), solder, or the like. However, these materials are only an example, and a material of the connection terminal 190 is not particularly limited thereto. The connection terminal 190 may be a land, a ball, a pin, or the like. The connection terminal 190 may be formed of multiple layers or a single layer. In a case in which the connection terminal 190 is formed of the multiple layers, the connection terminal 190 may include a copper pillar and solder, and in a case in which the connection terminal 190 is formed of the single layer, the connection terminal 190 may include tin-silver solder or copper. However, this is only an example, and the connection terminal 190 is not limited thereto.

At least one of the connection terminals 190 may be disposed in a fan-out region. The fan-out region is a region except for a region in which the electronic component is disposed. That is, the electronic component package 100, according to an example, may be a fan-out package. The fan-out package may have excellent reliability as compared to a fan-in package, may implement a plurality of input/output (I/O) terminals, and may facilitate a 3D interconnection. In addition, as compared to a ball grid array (BGA) package, a land grid array (LGA) package, or the like, the fan-out package may be mounted on an electronic device without a separate board. Thus, the fan-out package may be manufactured to be thin, and may have a competitive price.

The number, an interval, a disposition form, or the like, of the connection terminals 190 is not particularly limited, and may be sufficiently modified by a person skilled in the art depending on design particulars. For example, the number of connection terminals 190 may be several tens to several thousands, depending on the number of electrode pads 120P of the first electronic component 120. However, the number of connection terminals 190 is not limited thereto, and may also be several tens to several thousand or more, or several tens to several thousand or less.

Next, the upper package 300 will be described. As described above, the upper package 300 may be disposed on the lower package 200, and may include a second electronic component 142. The second electronic component 142 may be a memory element, or the like, and the electronic component package 100 may be implemented in a package-on-package form. In this case, for a certain form of the upper package 300, a packaging form of the second electronic component 142, or the like, or the contents known in the related art may be referred to. For example, a package base 140 having a form in which the second electronic component 142 is molded with an insulating resin, or the like, may be provided.

One or more passive elements 160 may be disposed between the upper package 300 and the lower package 200. As an example, as in the form illustrated in FIG. 3, the passive element 160 may be provided in a form in which it is mounted on the lower package 200 and is electrically connected to the lower package 200. To improve performance of the electronic component package 100, the number of passive elements 160 that are required has increased, and typical examples of the passive element 160 may include a capacitor, an inductor, a resistor, and the like.

In detail, the passive element 160 may include a decoupling capacitor, provided in order to stably supply power to the first electronic component 120, and the like. To this end, the passive element 160 may be connected to the above-mentioned power patterns of the wiring layers 113, 114, 115, 132, and 152. The passive element 160 may be connected to the first electronic component 120, such as the integrated circuit, or the like, by the power patterns, to serve as the decoupling capacitor.

Meanwhile, in relation to a disposition region of the passive element 160, a scheme in which the passive element 160 is embedded in the redistribution layer or is mounted below the redistribution layer has been used in a package according to the related art. In this case, there was a problem that a region occupied by the connection terminals below the redistribution layer was reduced or a size of the package itself was increased.

In the present exemplary embodiment, a main disposition region of the passive element 160 is set to a region between the upper package 300 and the lower package 200. Therefore, a sufficient number of connection terminals 190 below the electronic component package 100 may be secured, and a size of the electronic component package 100 may be reduced. In order to implement the disposition form of the passive element 160 described above, sizes of conductive adhesive layers 141, such as solders connecting the upper package 300 and the lower package 200 to each other, may be selected in consideration of a size of the passive element 160.

In detail, as in the form illustrated in FIG. 3, heights of the conductive adhesive layers 141 may be set to be higher than that of the passive element 160. Therefore, the passive element 160 may have a form in which it is disposed to be spaced apart from the upper package 300. In addition, a plurality of conductive adhesive layers 141 may be disposed to surround the passive element 160 to thus implement a stable mounted form of the passive element 160.

Meanwhile, although it is suggested that it is preferable to dispose the passive element 160 between the upper package 300 and the lower package 200 in the above-mentioned exemplary embodiment, the passive element 160 is not limited thereto, but may also be disposed in another position. For example, as in a modified example shown in FIG. 4, an additional passive element 161 may be disposed below the lower package 200, and, more specifically, below the redistribution layer 150, depending on a required function.

As set forth above, according to the exemplary embodiment in the present disclosure, an electronic component package in which a plurality of elements may be mounted in a small space may be provided. Therefore, performance improvement and miniaturization of the electronic component package may be implemented.

In the present disclosure, the terms “lower side”, “lower portion”, “lower surface”, and the like, have been used to indicate a direction toward a mounted surface of the electronic component package in relation to cross sections of the drawings, and the terms “upper side”, “upper portion”, “upper surface”, and the like, have been used to indicate an opposite direction to the direction indicated by the terms “lower side”, “lower portion”, “lower surface”, and the like. However, these directions are defined for convenience of explanation only, and the claims are not particularly limited by the directions defined as described above.

The meaning of a “connection” of a component to another component in the description includes an indirect connection through an adhesive layer, as well as a direct connection between two components. In addition, “electrically connected” may includes a physical connection and/or a physical disconnection. It can be understood that when an element is referred to as “first” or “second”, the element is not limited thereby. These terms may be used only for a purpose of distinguishing the element from the other elements, and may not limit the sequence or importance of the elements. In some cases, a first element may be referred to as a second element without departing from the scope of the claims set forth herein. Similarly, a second element may also be referred to as a first element.

The term, “an exemplary embodiment,” used herein does not always refer to the same exemplary embodiment, and is provided to emphasize a particular feature or characteristic that is different from that of another exemplary embodiment. However, the exemplary embodiments provided herein are considered to be executable by being combined in whole or in part with one another. For example, one element described in a particular exemplary embodiment, even if it is not described in another exemplary embodiment, may be understood as a description applying to another exemplary embodiment unless an opposite or contradictory description is provided therein.

Terms used herein are used only in order to describe an exemplary embodiment rather than to limit the present disclosure. In this case, singular forms include plural forms unless necessarily interpreted otherwise, in a particular context.

While exemplary embodiments have been shown and described above, it will be apparent to those skilled in the art that modifications and variations could be made without departing from the scope of the present invention as defined by the appended claims.

What is claimed is:

1. An electronic component package comprising:
a lower package including a frame including a through-hole and a through-wiring, a first electronic component disposed in the through-hole of the frame, a redistribution layer disposed below the first electronic component and the frame and electrically connected to the first electronic component, and an encapsulant filling the through-hole to encapsulate the first electronic component;
an upper package disposed on the lower package and including a second electronic component; and
a passive element disposed between the upper package and the lower package.

2. The electronic component package of claim 1, further comprising a conductive adhesive layer connecting the upper package and the lower package to each other.

3. The electronic component package of claim 2, wherein the conductive adhesive layer is a solder.

4. The electronic component package of claim 2, wherein a height of the conductive adhesive layer is higher than that of the passive element.

5. The electronic component package of claim 4, wherein the passive element is disposed to be spaced apart from the upper package.

6. The electronic component package of claim 1, further comprising a plurality of conductive adhesive layers connecting the upper package and the lower package to each other and surrounding the passive element.

7. The electronic component package of claim 1, wherein the passive element is mounted on the lower package, and is electrically connected to the lower package.

8. The electronic component package of claim 1, further comprising an additional passive element disposed below the lower package.

9. The electronic component package of claim 1, wherein the through-wiring electrically connects the upper package and the lower package to each other.

10. The electronic component package of claim 9, wherein the encapsulant covers an upper portion of the frame, and the lower package further includes a conductive via penetrating therethrough a portion of the encapsulant covering the upper portion of the frame and electrically connected to the through-wiring.

11. The electronic component package of claim 1, wherein the first electronic component is an active element, and the second electronic component is a memory element.

12. The electronic component package of claim 1, wherein the passive element is connected to the first electronic component by power patterns of wiring layers included in the lower package.

13. The electronic component package of claim 12, wherein the passive element is a decoupling capacitor.
